(19) United States
(12) Patent Application Publication
(10) Pub. No.: US 2026/0143701 A1
(43) Pub. Date: May 21, 2026

(54) MEMORY DEVICE AND METHOD OF FABRICATING THE SAME

(71) Applicant: MACRONIX International Co., Ltd., Hsinchu (TW)

(72) Inventor: Chin-Cheng Yang, Kaohsiung City (TW)

(73) Assignee: MACRONIX International Co., Ltd., Hsinchu (TW)

(21) Appl. No.: 18/954,940

(22) Filed: Nov. 21, 2024

(51) Int. Cl. H10B 43/27; H10B 41/27

(52) U.S. Cl. CPC H10B 43/27; H10B 41/27

(57) ABSTRACT

A memory device includes a substrate, first and second stack structures, a plurality of first and second protrusion portions, and a plurality of conductive plugs. The memory device may be a three-dimensional NAND flash memory with high capacity and high performance. The plurality of first protrusion portions are disposed on and electrically connected to a plurality of first conductive layers of a first staircase structure of the first stack structure. The plurality of second protrusion portions are disposed on and are electrically connected to a plurality of second conductive layers of a second staircase structure of the second stack structure. The plurality of conductive plugs extend through the second staircase structure and the first staircase structure, and each conductive plug is electrically connected to one of the plurality of first conductive layers and the plurality of second conductive layers respectively, and is surrounded by and electrically connected to one of the plurality of first protrusion portions and the plurality of second protrusion portions.

### BACKGROUND

### Technical Field

The disclosure relates to a semiconductor structure and a method of fabricating the same, and particularly relates to a memory device and a method of fabricating the same.

### Description of Related Art

As the integration density of memory devices increases, in order to achieve high density and high performance, it has become a trend to replace two-dimensional memory devices with three-dimensional memory devices. Vertical memory devices are one type of the three-dimensional memory devices. Although the vertical memory devices may increase the memory capacity per unit area, the difficulty of interconnection in the vertical memory devices are also increased.

Generally speaking, the three-dimensional memory devices often use conductive layers with a staircase structure as pads, and then use conductive plugs on the pads to connect to upper interconnection structures or other components. However, due to the different depths of the conductive plugs, during the etching process for forming the conductive plug openings, the conductive plug openings with a shallower depth are prone to over etching problems, which may even extend to the conductive layers thereunder. This results in unnecessary bridging between the conductive plugs and other conductive layers, thus causing an electrical short circuit of the device. Therefore, how to prevent electrical short circuit problems caused by over etching during the conductive plug opening process is currently an important issue.

### SUMMARY

An embodiment of the disclosure provides a memory device, including: a substrate, a first stack structure, a second stack structure, a plurality of first protrusion portions, a plurality of second protrusion portions, and a plurality of conductive plugs. A first stack structure is located on the substrate. The first stack structure includes a plurality of first conductive layers and a plurality of first insulating layers alternating with each other, and the first stack structure in a staircase region of the substrate includes a first staircase structure. The second stack structure is located on the first stack structure. The second stack structure includes a plurality of second conductive layers and a plurality of second insulating layers alternating with each other, and the second stack structure in the staircase region of the substrate includes a second staircase structure. The plurality of first protrusion portions are disposed on the plurality of first conductive layers of the first staircase structure and electrically connected to the plurality of first conductive layers. The plurality of second protrusion portions are disposed on the plurality of second conductive layers of the second staircase structure and electrically connected to the plurality of second conductive layers. The plurality of conductive plugs extend through the second staircase structure and the first staircase structure, and each conductive plug is electrically connected to one of the plurality of first conductive layers and the plurality of second conductive layers respectively, and is surrounded by and electrically connected to one of the plurality of first protrusion portions and the plurality of second protrusion portions.

The disclosure provides a method of fabricating a memory device, which includes the following steps. A substrate is provided. A first stack structure is formed on the substrate. The first stack structure includes a plurality of first conductive layers and a plurality of first insulating layers alternating with each other, and the first stack structure in a staircase region of the substrate includes a first staircase structure. A second stack structure is formed on the first stack structure. The second stack structure includes a plurality of second conductive layers and a plurality of second insulating layers alternating with each other, and the second stack structure in the staircase region of the substrate includes a second staircase structure. A plurality of first protrusion portions are formed on the plurality of first conductive layers of the first staircase structure and electrically connected to the plurality of first conductive layers. A plurality of second protrusion portions are formed on the plurality of second conductive layers of the second staircase structure and electrically connected to the plurality of second conductive layers. A plurality of conductive plugs are formed to extend through the second staircase structure and the first staircase structure, and each conductive plug is electrically connected to one of the plurality of first conductive layers and the plurality of second conductive layers respectively, and is surrounded by and electrically connected to one of the plurality of first protrusion portions and the plurality of second protrusion portions.

Based on the above, in the memory device and the method of fabricating the same proposed in the embodiment of the disclosure, the plurality of conductive plugs connected to the plurality of conductive layers have substantially the same depth. Therefore, there will be no over etching problems caused by the plurality of conductive plug openings with different depths. Furthermore, the contact area between the conductive layer and the conductive plug may be increased and the contact resistance may be reduced by forming the protrusion portion around the conductive plug.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1A to FIG. 1R are cross-sectional views of a fabricating process of a memory device according to some embodiments of the disclosure.

FIG. 2A to FIG. 2C are another cross-sectional view of a fabricating process of a memory device according to other embodiments of the disclosure.

FIG. 3A to FIG. 3K are cross-sectional views of a fabricating process of a memory device in the partial region of FIG. 1R.

FIG. 4A to FIG. 4C are top views of some stages of a fabricating process of a memory device according to some embodiments of the disclosure.

FIG. 5A to FIG. 5C are top views of some stages of a fabricating process of a memory device according to other embodiments of the disclosure.

FIG. 6A to FIG. 6D are top views of some stages of a fabricating process of a memory device according to other embodiments of the disclosure.

### DESCRIPTION OF THE EMBODIMENTS

The embodiments are described in detail below with reference to the accompanying drawings, but the embodiments are not intended to limit the scope of the disclosure. For the sake of easy understanding, the same components in the following description will be denoted by the same reference symbols. In addition, the drawings are for illustrative purposes only and are not drawn to original dimensions. Furthermore, the features in the top view and the features in the cross-sectional view are not drawn to the same scale. In fact, the dimensions of the various features may be arbitrarily increased or reduced for clarity of discussion.

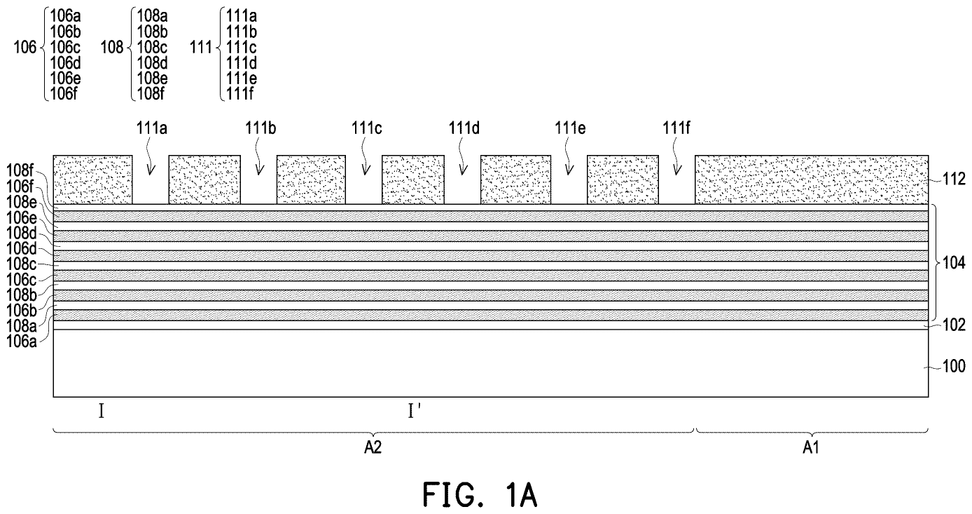

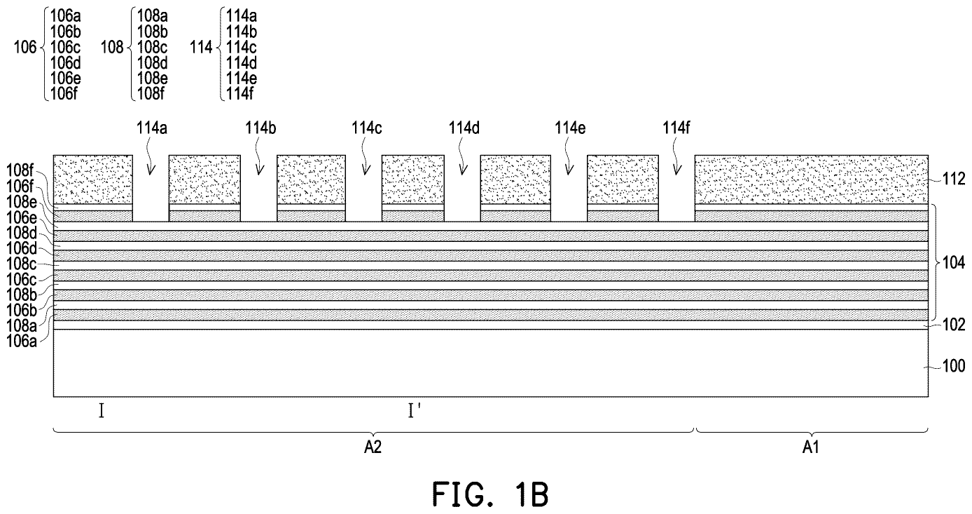

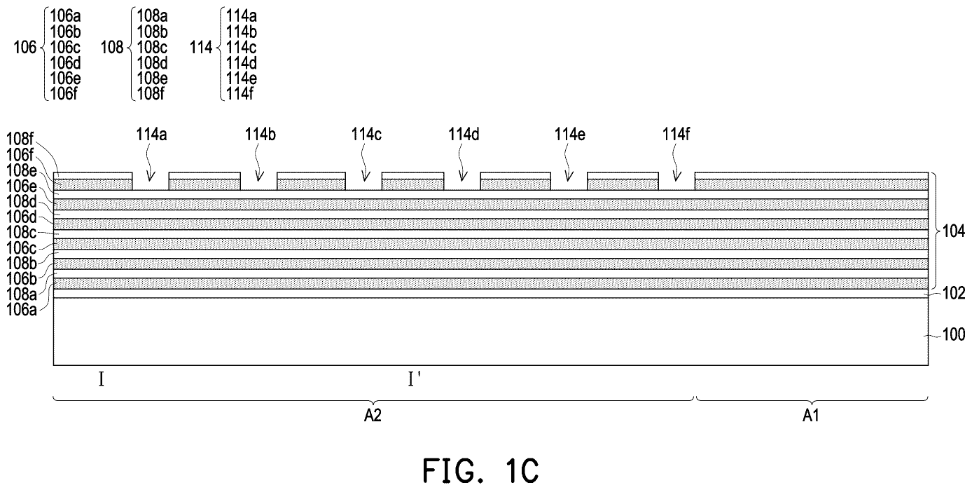

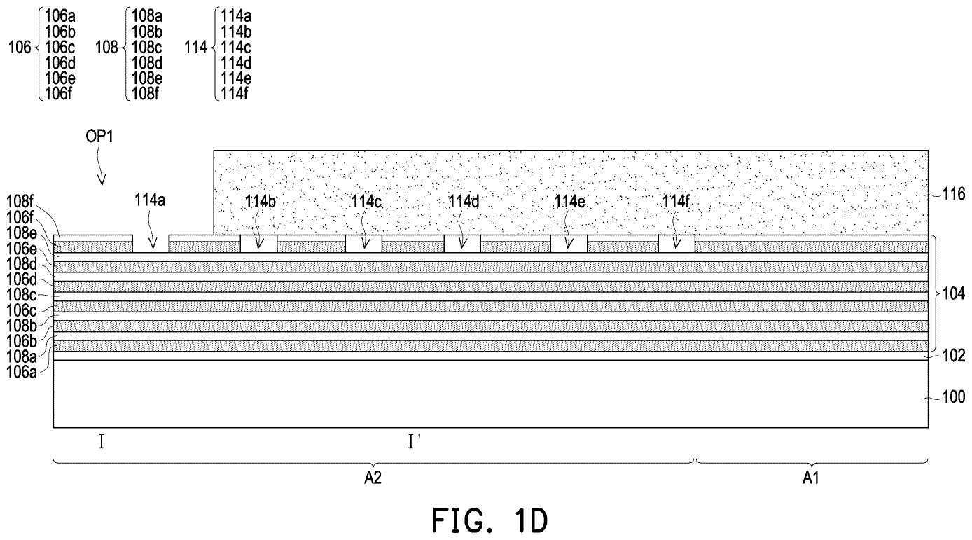

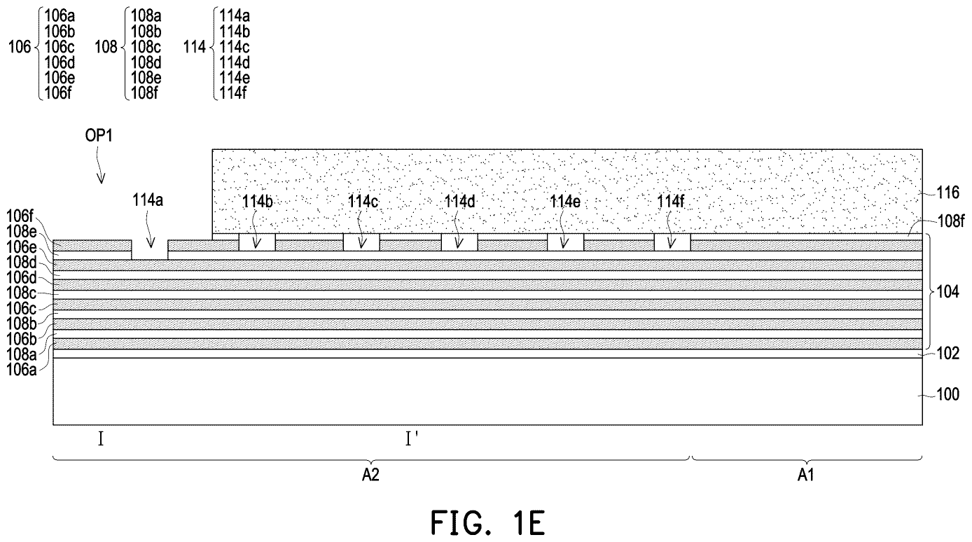

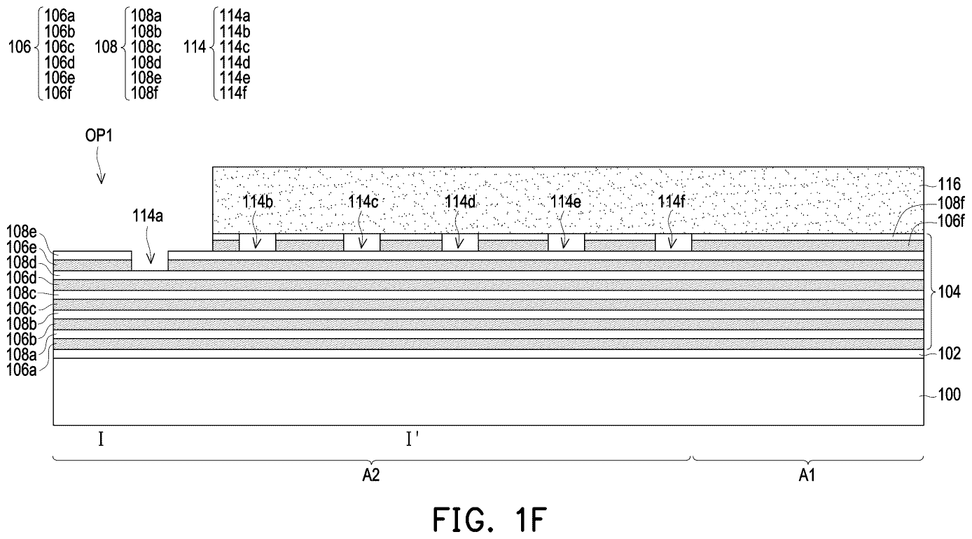

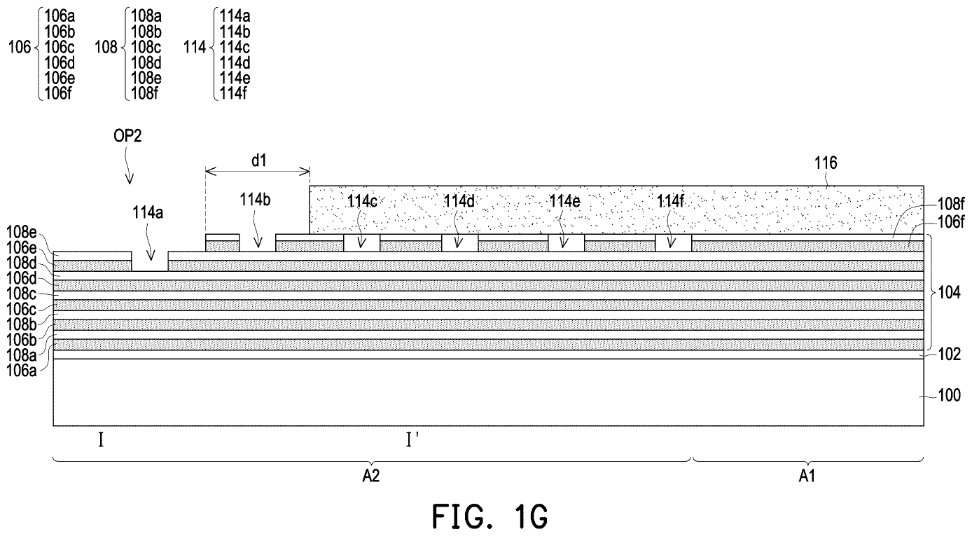

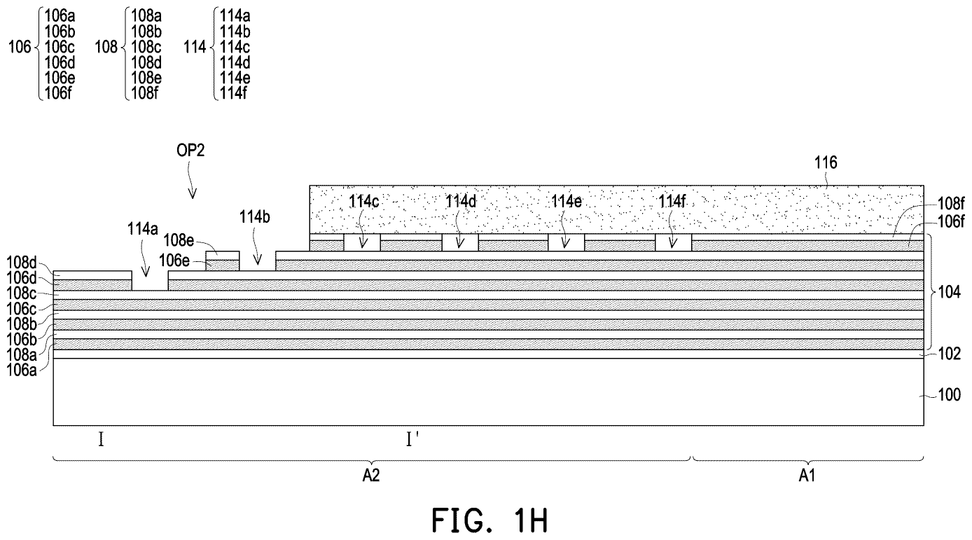

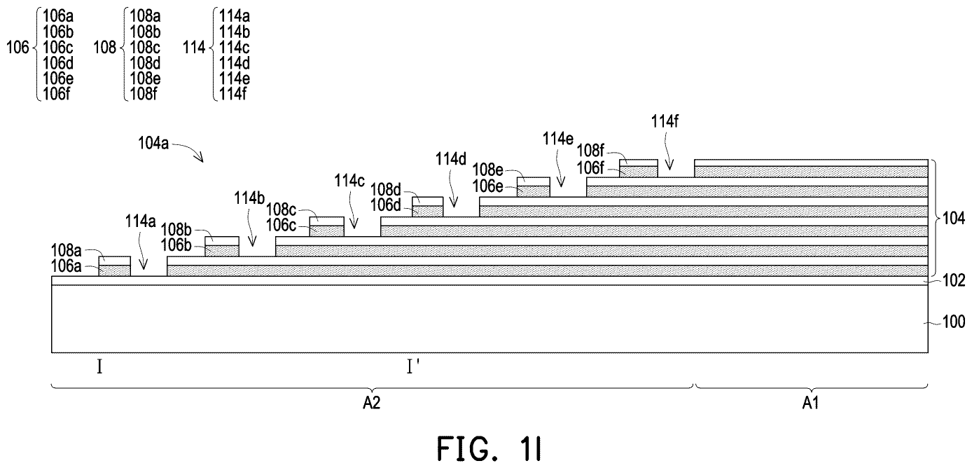

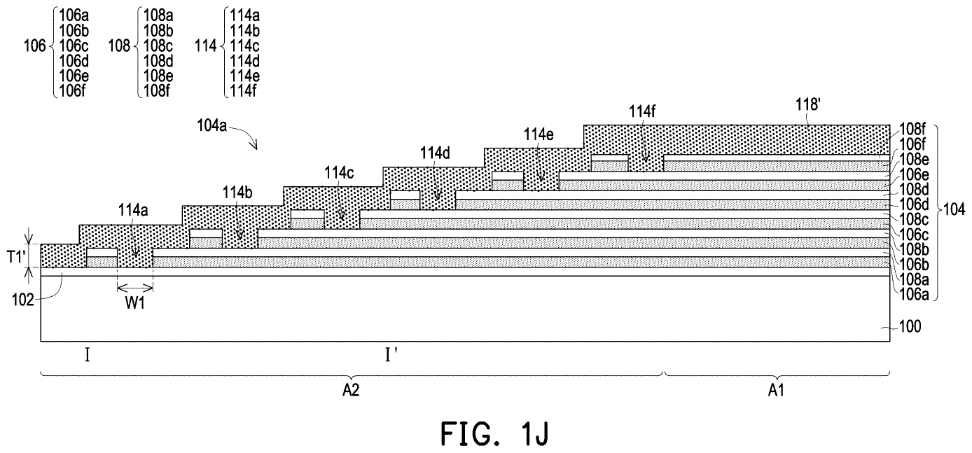

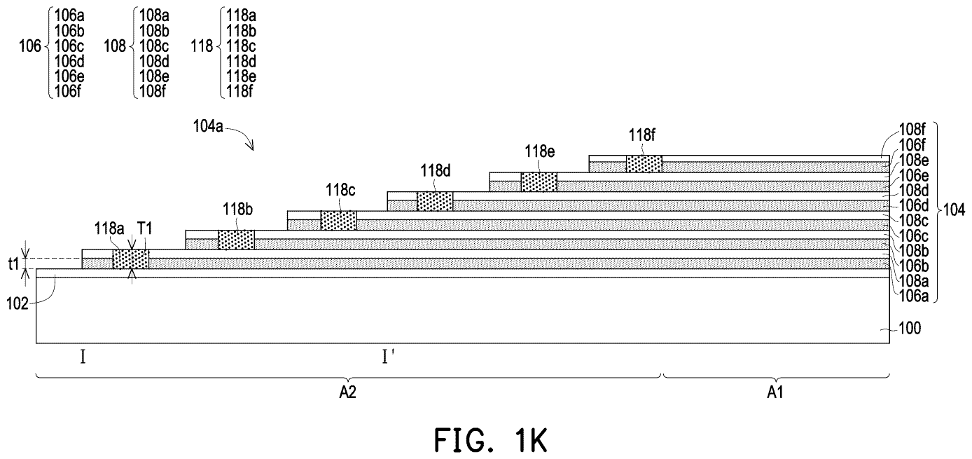

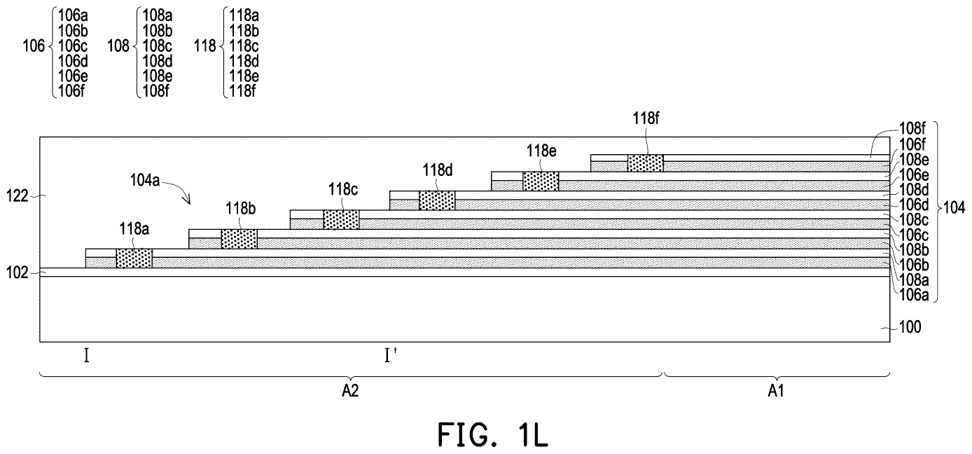

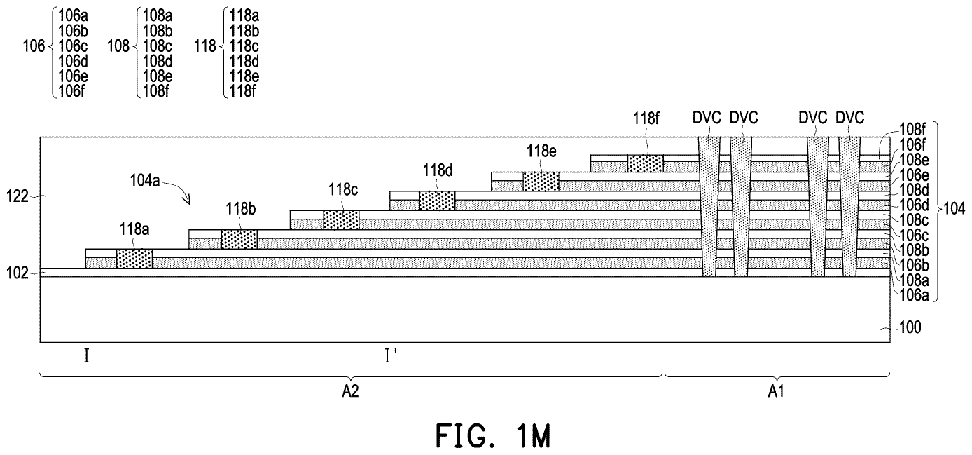

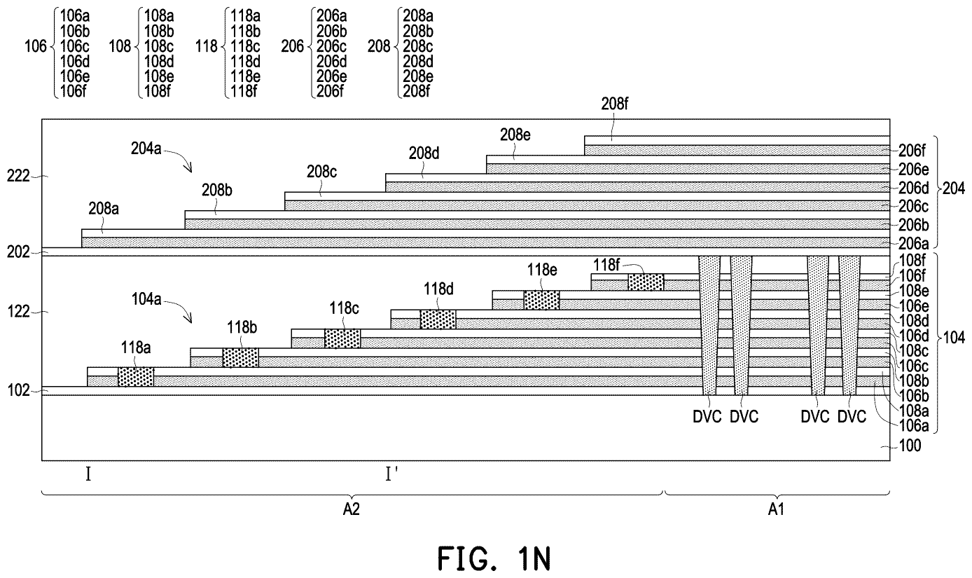

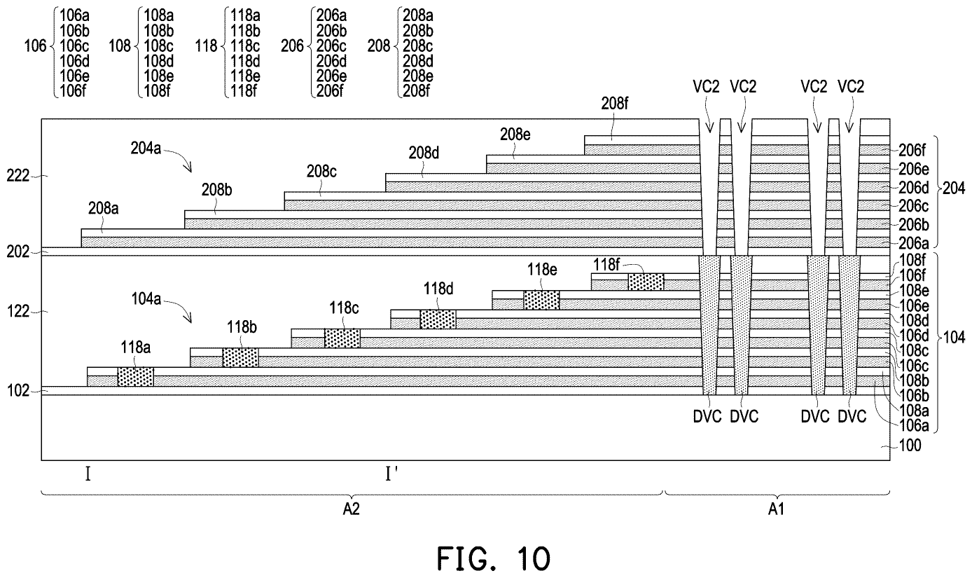

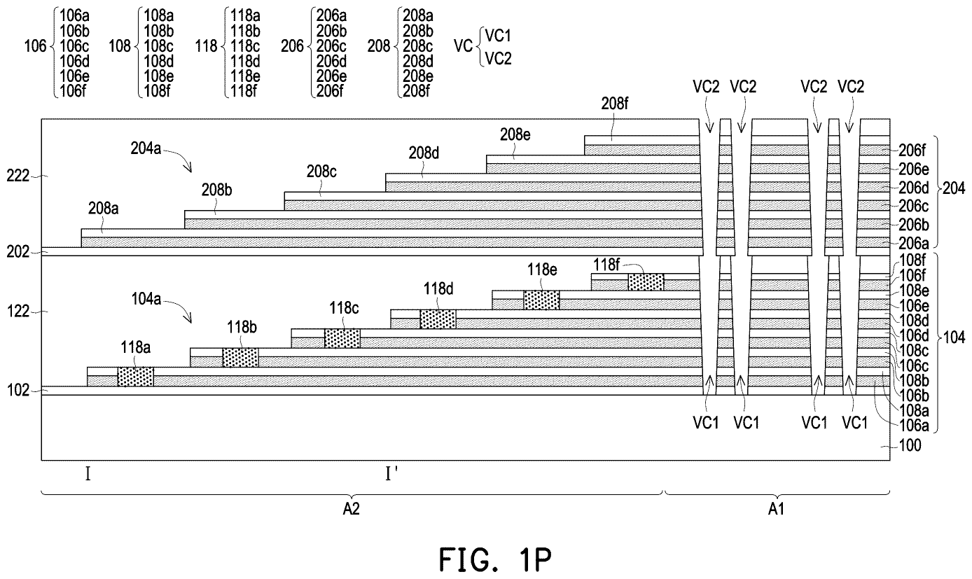

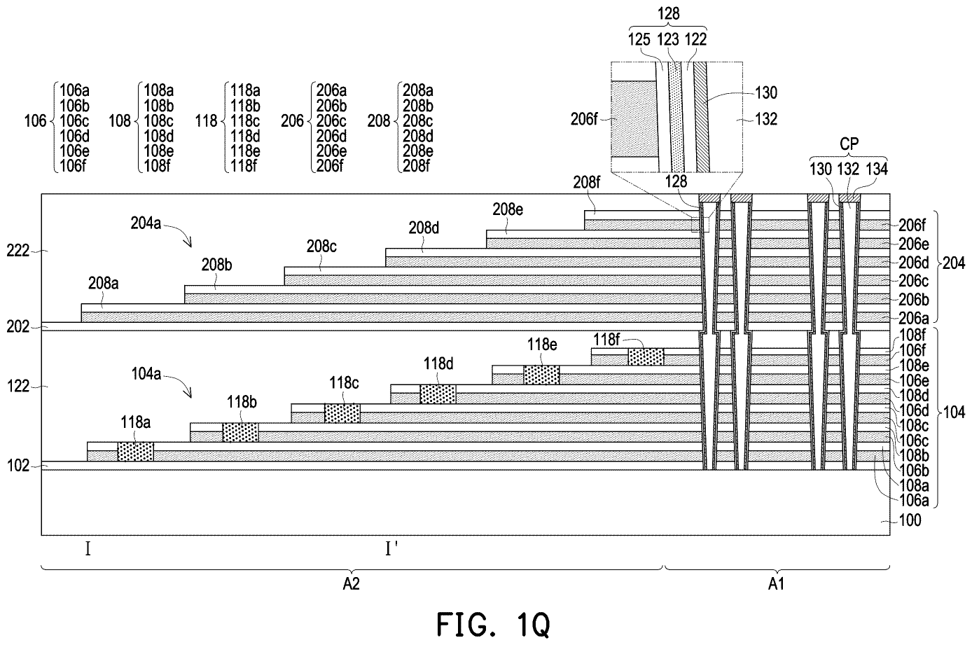

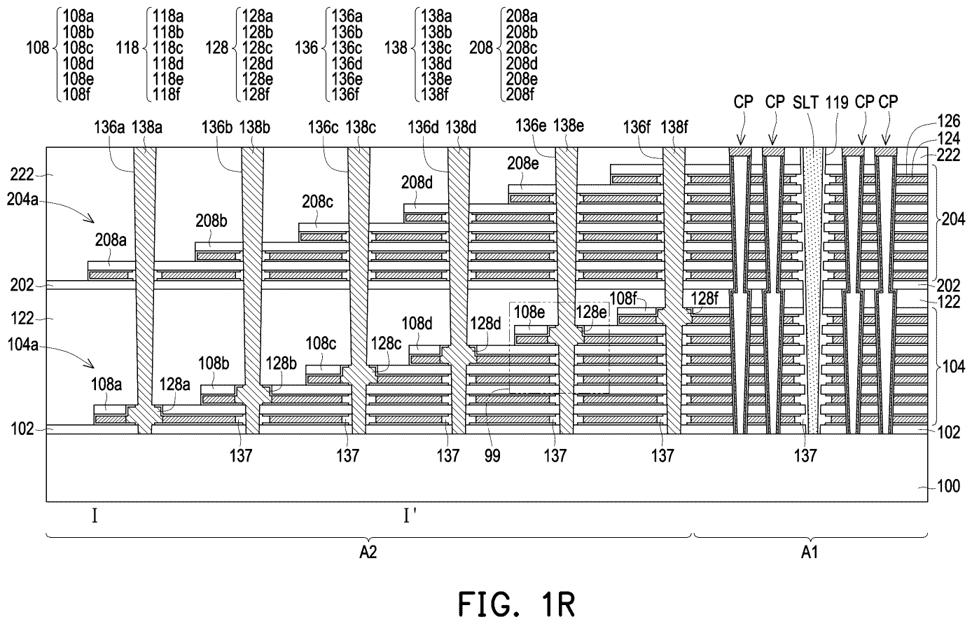

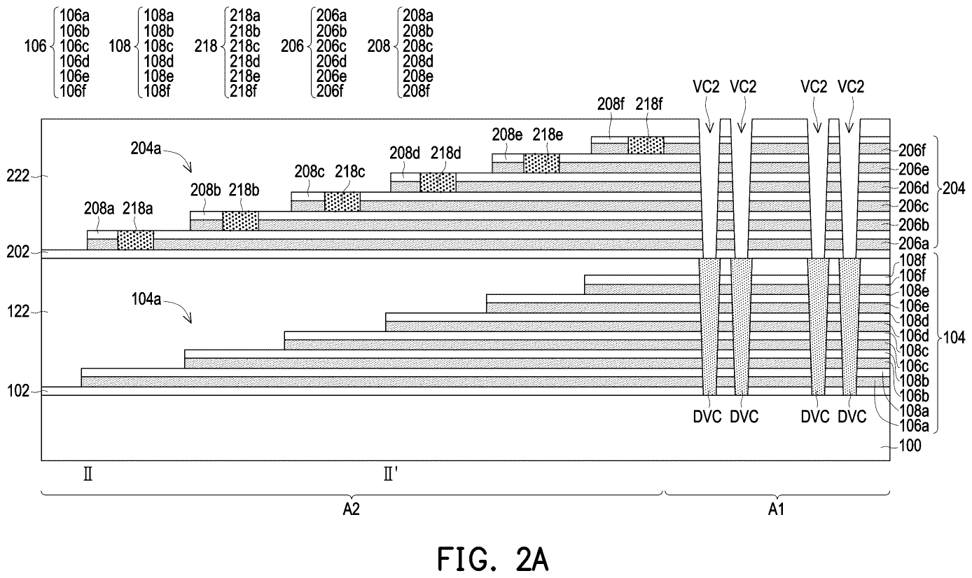

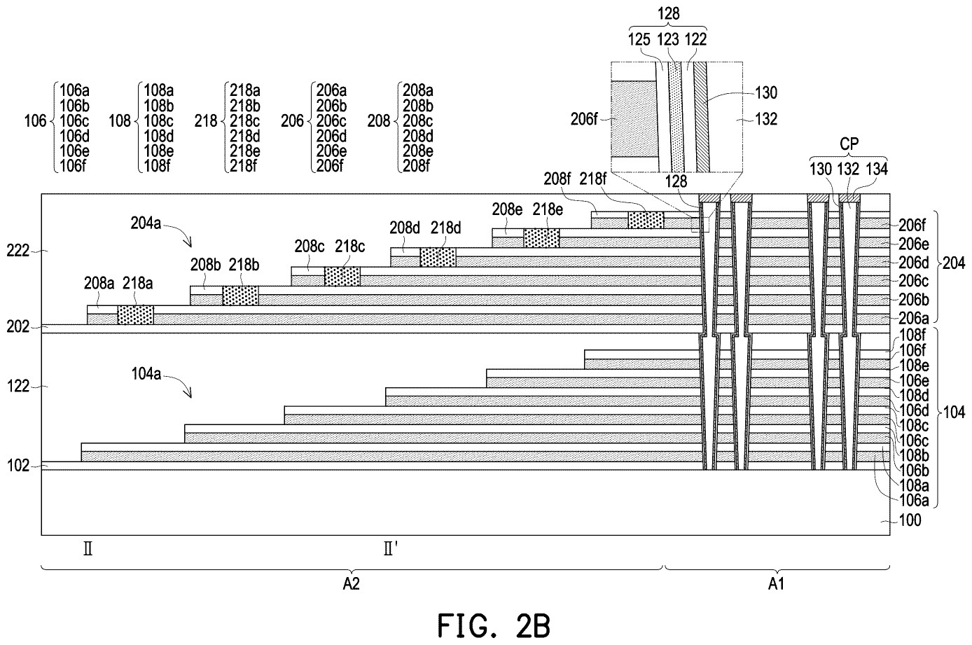

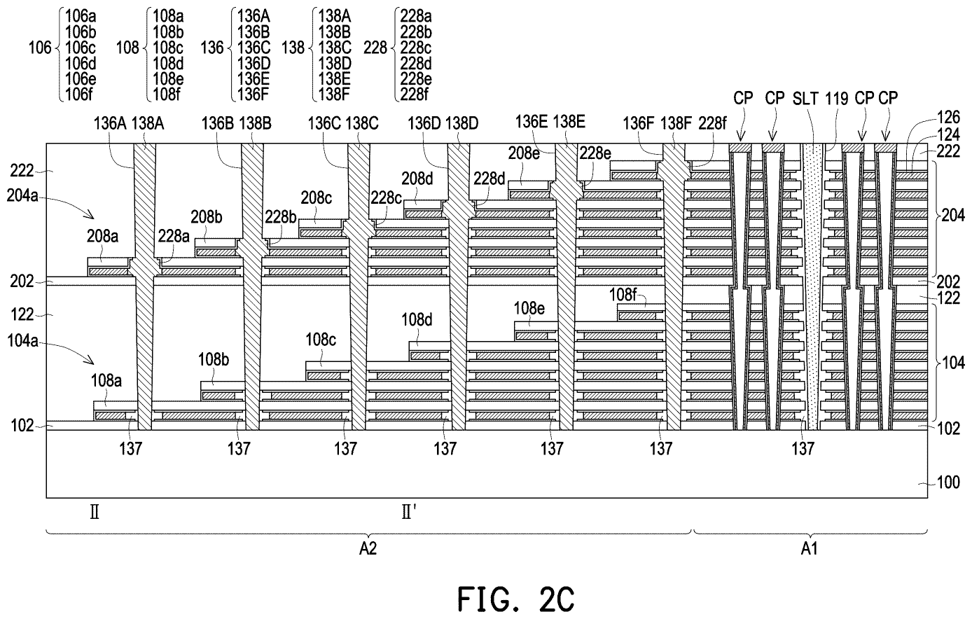

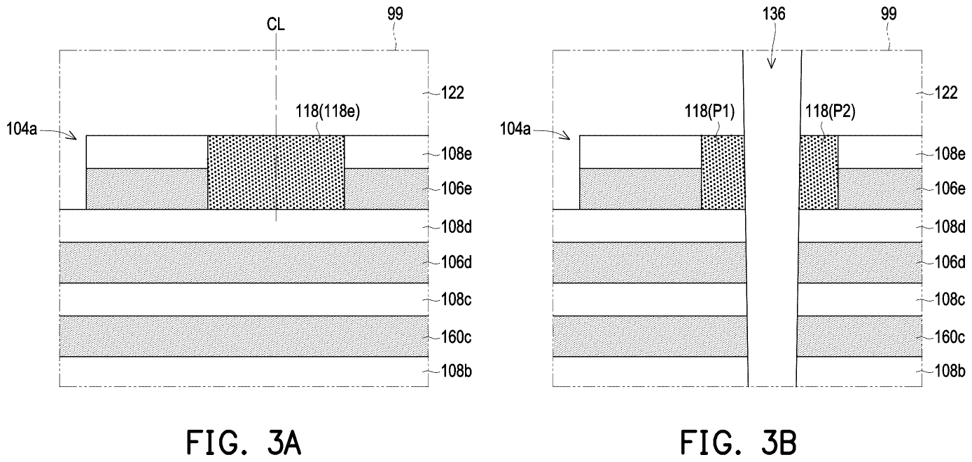

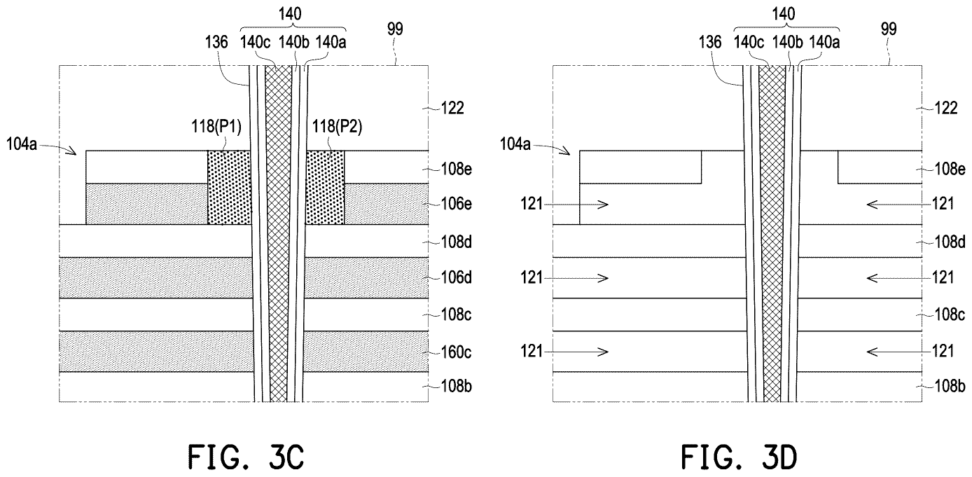

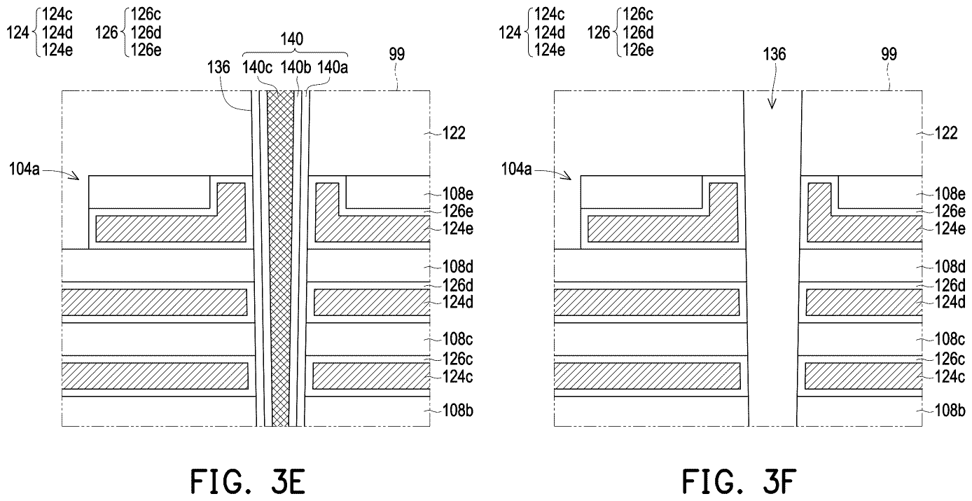

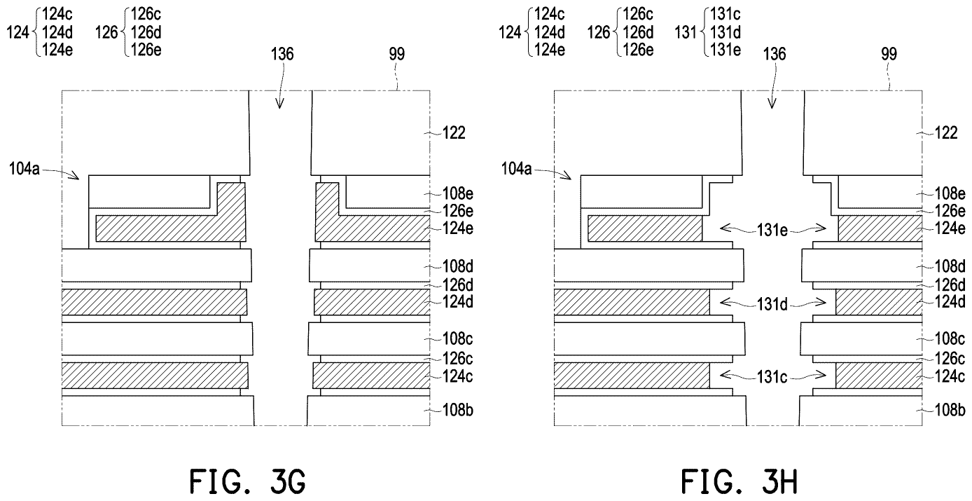

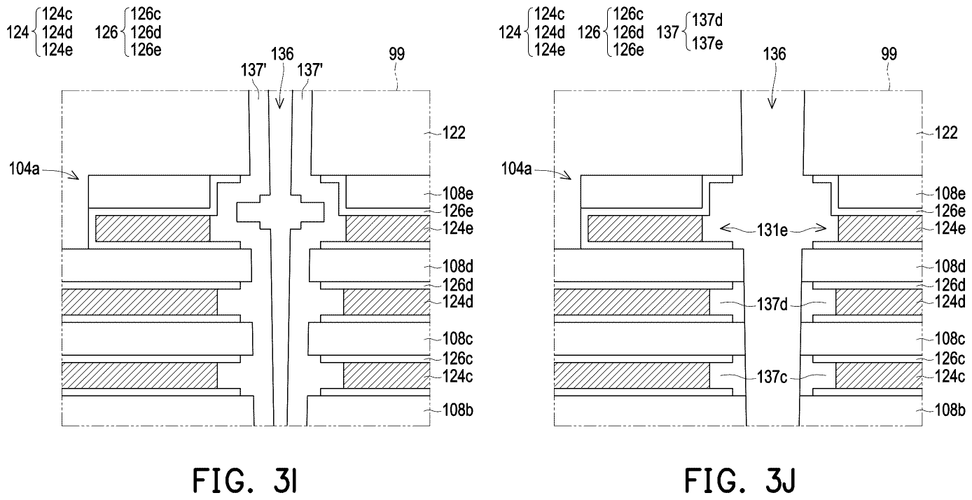

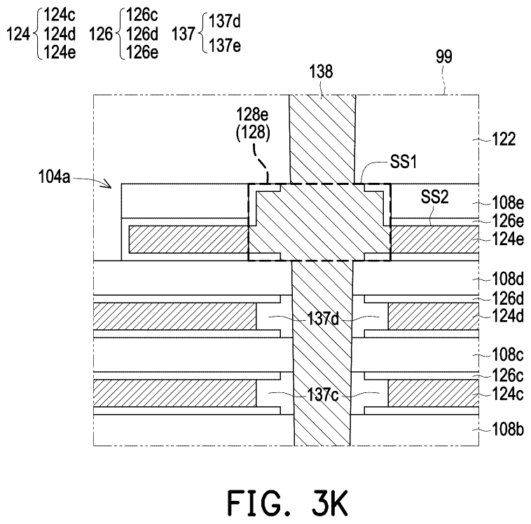

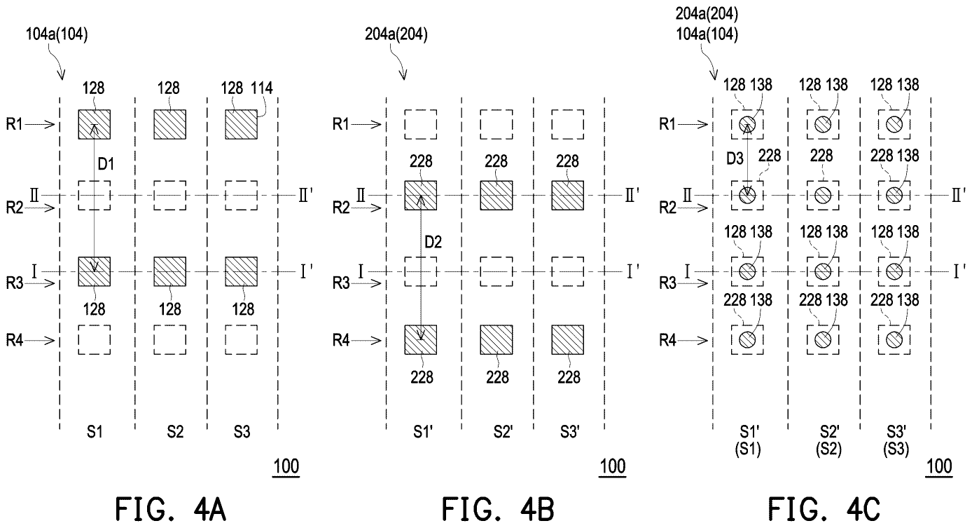

FIG. 1A to FIG. 1R are cross-sectional views of a fabricating process of a memory device according to some embodiments of the disclosure. FIG. 2A to FIG. 2C are another cross-sectional view of a fabricating process of a memory device according to other embodiments of the disclosure. FIG. 1A to FIG. 1R are cross-sectional views along line I-I′ in FIG. 4A to FIG. 4C. FIG. 2A to FIG. 2C are cross-sectional views along line II-II′ in FIG. 4A to FIG. 4C. FIG. 3A to FIG. 3K are cross-sectional views of a fabricating process of a memory device in the partial region of FIG. 1R. FIG. 4A to FIG. 4C are top views of some stages of a fabricating process of a memory device according to some embodiments of the disclosure. In the top view of the present embodiment, some components in the cross-sectional view are omitted to clearly illustrate the configuration relationship between the components in the top view.

Referring to FIG. 1A, a substrate 100 is provided. The substrate 100 may include a memory cell array region A1 and a staircase region A2. In some embodiments, the substrate 100 may be a semiconductor substrate (e.g., silicon substrate), a compound semiconductor substrate (e.g., gallium arsenide substrate), or a semiconductor-on-insulator (SOI) substrate, but the disclosure is not limited thereto. In addition, although not shown in FIG. 1A, the memory cell array region A1 and the staircase region A2 of the substrate 100 may be provided with required components such as various devices (such as active devices and/or passive devices), interconnection structures, and/or dielectric layers thereon, and a description thereof is omitted here.

Next, a protective layer 102 is formed on the memory cell array region A1 and the staircase region A2 of the substrate 100. In some embodiments, the material of the protective layer 102 is, for example, silicon oxide. In some embodiments, the method of forming the protective layer 102 is, for example, a chemical vapor deposition method. Then, a first stack structure 104 may be formed on the protective layer 102. The first stack structure 104 includes a plurality of middle layers 106 (e.g., middle layers 106a to 106f) and a plurality of insulating layers 108 (e.g., insulating layers 108a to 108f) that are alternately stacked. In some embodiments, the material of the middle layer 106 is, for example, silicon nitride. The method of forming the middle layer 106 is, for example, a chemical vapor deposition method. In some embodiments, the material of the insulating layer 108 is, for example, silicon oxide. The method of forming the insulating layer 108 is, for example, a chemical vapor deposition method. Next, a patterned photoresist layer 112 may be formed on the first stack structure 104. In some embodiments, the patterned photoresist layer 112 may be formed by a photolithography process. The patterned photoresist layer 112 in the staircase region A2 has a plurality of openings 111 (111a to 111f).

Referring to FIG. 1B, using the patterned photoresist layer 112 as a mask, the insulating layer 108f and the middle layer 106f exposed by the plurality of openings 111 are removed, and a plurality of openings 114 (e.g., openings 114a to 114f) are formed in the insulating layer 108f and the middle layer 106f. In some embodiments, the method of removing part of the insulating layer 108f and part of the middle layer 106f is, for example, a dry etching method.

Referring to FIG. 1C, next, the patterned photoresist layer 112 is removed to expose the insulating layer 108f and the plurality of openings 114 (e.g., openings 114a to 114f). The method of removing the patterned photoresist layer 112 is, for example, a dry stripping method or wet stripping method.

Afterwards, a patterned photoresist layer 116 is formed on the first stack structure 104. An opening OP1 of the patterned photoresist layer 116 may expose the opening 114a and part of the insulating layer 108f. In some embodiments, the patterned photoresist layer 116 may be formed by a photolithography process.

Referring to FIG. 1E, using the patterned photoresist layer 116 as a mask, the etching process is performed to remove part of the insulating layer 108f exposed by the opening OP1 of the patterned photoresist layer 116 and part of the insulating layer 108e located below the opening 114a, so that the pattern of the opening 114a is transferred to the insulating layer 108e. Thereby, the patterned photoresist layer 116 exposes the middle layer 106f, and the opening 114a exposes the middle layer 106d. In addition, during this step, the patterned photoresist layer 116 may be etched, so that the thickness of the patterned photoresist layer 116 is slightly reduced. In some embodiments, the etching process may be a dry etching process, such as a reactive ion etching process.

Referring to FIG. 1F, using the patterned photoresist layer 116 as a mask, the etching process is performed to remove the middle layer 106f exposed by the opening OP1 of the patterned photoresist layer 116 and the middle layer 106d exposed by the opening 114a, so that the pattern of the opening 114a is transferred to the insulating layer 108e and the middle layer 106d. In addition, during this step, the patterned photoresist layer 116 may be etched, so that the thickness of the patterned photoresist layer 116 is slightly reduced. In some embodiments, the etching process may be a dry etching process, such as a reactive ion etching process.

Referring to FIG. 1G, a trimming process may be performed on the patterned photoresist layer 116, so that the opening OP1 is enlarged into an opening OP2 to further expose an opening 114b. The above trimming process refers to pulling back the patterned photoresist layer 116 by a distance d1. In this way, as shown in FIG. 1G, the opening OP2 may expose the opening 114a and the opening 114b. In some embodiments, when trimming the patterned photoresist layer 116, the thickness of the patterned photoresist layer 116 may also be slightly reduced. In some embodiments, the trimming process may be performed by a dry etching process.

Referring to FIG. 1H, the above steps are repeated, and using the patterned photoresist layer 116 as a mask, the etching process is performed to remove part of the insulating layer 108f, part of the middle layer 106f, part of the insulating layer 108e, part of the middle layer 106e, part of the insulating layer 108d, and part of the middle layer 106d exposed by the opening OP1, so that the pattern shape of the opening 114a is transferred to the insulating layer 108d and part of the middle layer 106d, and the pattern shape of the opening 114b is transferred to the insulating layer 108e and part of the middle layer 106e. Thereby, the opening 114a may expose the insulating layer 108c, and the opening 114b may expose the insulating layer 108d. In addition, during this step, the patterned photoresist layer 116 may also be etched, so that the thickness of the patterned photoresist layer 116 is slightly reduced. In some embodiments, the etching process may be a dry etching process, such as a reactive ion etching process.

Referring to FIG. 1I, a trimming process is further performed on the patterned photoresist layer 116 to expose an opening 114c. Thereafter, the above etching process and the above trimming process are repeated until a first staircase structure 104a as shown in FIG. 1I is formed. After the first staircase structure 104a is formed, the patterned photoresist layer 116 may be removed. In some embodiments, the method of removing the patterned photoresist layer 116 is, for example, a dry stripping method or a wet stripping method. Through the above method, the first stack structure 104 on the staircase region A2 of the substrate 100 may be patterned, and the first staircase structure 104a is formed in the staircase region A2, and the plurality of openings 114 are formed in each step of the first staircase structure 104a. In some embodiments, each opening 114 may penetrate an insulating layer 108 and a middle layer 106.

Referring to FIG. 1J and FIG. 4A, the top view pattern of the opening 114 is square, but the disclosure is not limited thereto. In other embodiments, the top view pattern of the opening 114 may be rectangular, bar-shaped, polygonal, circular, or oval.

Referring to FIG. 1J, a buried layer 118′ is conformally formed on a plurality of upper surfaces and a plurality of side surfaces of the first staircase structure 104a and in the plurality of openings 114. In some embodiments, a thickness T1′ of the buried layer 118′ may be greater than or equal to one-half a width W1 of the opening 114. The material of the buried layer 118′ may be the same as or different from the middle layer 106 and a middle layer 206. In some embodiments, the material of the buried layer 118′ is, for example, silicon nitride. In some embodiments, the method of forming the buried layer 118′ is, for example, a chemical vapor deposition method.

Referring to FIG. 1K, an etching back process is performed on the buried layer 118′ to remove the buried layer 118′ outside the opening 114, and a buried pad 118 (118a to 118f) is formed in the opening 114 (114a to 114f). The etching back process is, for example, an anisotropic etching process. A thickness T1 of the buried pad 118 remaining in the plurality of openings 114 is greater than a thickness t1 of the middle layer 106.

Referring to FIG. 1L, a dielectric layer 122 is formed on the first staircase structure 104a and the buried pad 118. The dielectric layer 122 may be a single-layer structure or a multi-layer structure. In some embodiments, the material of the dielectric layer 122 is, for example, silicon oxide. In some embodiments, the method of forming the dielectric layer 122 is, for example, a chemical vapor deposition method.

Referring to FIG. 1M and FIG. 4A, the top view pattern of the buried pad 118 located in the opening 114 is square, but the disclosure is not limited thereto. The top view pattern of the buried pad 118 located in the opening 114 may be rectangular, bar-shaped, polygonal, circular, or oval.

Referring to FIG. 1M, afterwards, a plurality of buried pillars DVC are formed in the dielectric layer 122 and the first stack structure 104 of the memory cell array region A1. The method of forming the buried pillar DVC includes, for example, the following steps. A photolithography and etching process is performed to form a plurality of first channel holes (not shown) in the dielectric layer 122 and the first stack structure 104. Next, a filling layer (not shown) is formed in the dielectric layer 122 and the plurality of first channel holes. Afterwards, the excess filling layer on the dielectric layer 122 is removed. The filling layer left in the channel holes forms the buried pillar DVC.

Referring to FIG. 1N and FIG. 2A, a protective layer 202, a second stack structure 204, a second staircase structure 204a, a buried pad 218 (218a to 218f, shown in FIG. 2A), and a dielectric layer 222 are formed according to the above method of forming the protective layer 102, the first stack structure 104, the first staircase structure 104a, the buried pad 118, and the dielectric layer 122. The second stack structure 204 includes a plurality of middle layers 206 (e.g., middle layers 206a to 206f) and a plurality of insulating layers 208 (e.g., insulating layers 208a to 208f) that are alternately stacked. A plurality of buried pads 218 (218a to 218f, shown in FIG. 2A) are buried in the plurality of middle layers 206 and the plurality of insulating layers 208. The top view pattern of the plurality of buried pads 218 may be square, but the disclosure is not limited thereto. The top view pattern of the buried pad 218 may be rectangular, bar-shaped, polygonal, circular, or oval.

Referring to FIG. 1O and FIG. 2A, a photolithography and etching process is performed to form a plurality of second channel holes VC2 in the dielectric layer 222, the second stack structure 204, and the protective layer 202. The second channel hole VC2 exposes the buried pillar DVC below.

Referring to FIG. 1P, an etching process is performed to remove the plurality of buried pillars DVC and form a plurality of first channel holes VC1 connected with the plurality of second channel holes VC2. The etching process may be a dry etching process or a wet etching process. The first channel hole VC1 and the second channel hole VC2 are collectively referred to as a hole VC.

Referring to FIG. 1Q, a charge storage structure 128 and a channel pillar CP are formed in the hole VC. The charge storage structure 128 may include a tunneling layer 122, a charge storage layer 123, and a barrier layer 125. The tunneling layer 122 is, for example, silicon oxide. The charge storage layer 123 is, for example, silicon nitride. The barrier layer 125 is, for example, silicon oxide. The charge storage structure 128 also includes a subsequently formed barrier layer 126 (shown in FIG. 1R).

Next, a channel layer 130 is formed on the charge storage structure 128. In an embodiment, the material of the channel layer 130 includes polysilicon. In an embodiment, the channel layer 130 covers the charge storage structure 128 on the sidewall of the hole VC, and also covers the charge storage structure 128 on the bottom surface of the hole VC. Next, an insulating pillar 132 is formed in the hole VC. In an embodiment, the material of the insulating pillar 132 includes silicon oxide. Afterwards, a conductive cap 134 is formed above the insulating pillar 132 of the hole VC, and the conductive cap 134 contacts and is electrically connected to the channel layer 130. In an embodiment, the material of conductive cap 134 includes polysilicon. The channel layer 130, the insulating pillar 132, and the conductive cap 134 may be collectively referred to as a channel pillar CP. The charge storage structure 128 surrounds the vertical outer surface of the channel pillar CP.

Referring to FIG. 1R and FIG. 2B, the middle layer 106 and the middle layer 206 are each replaced with the barrier layer 126 and a conductive layer 124 respectively, the buried pads 118 and 218 are replaced with a plurality of protrusion portions 128 and 228, and a plurality of conductive plugs 138 and a partition wall SLT are formed. The conductive layer 124 may serve as a word line. In the disclosure, the conductive layer 124 may be connected to the conductive plugs 138. The plurality of conductive plugs 138 may also be called the conductive plugs 138, and the partition wall SLT may also be called a slit SLT. The plurality of conductive plugs 138 extend below the protective layer 102 and are electrically connected to the interconnects of the interconnection structure below the protective layer 102. Therefore, the plurality of conductive plugs 138 have substantially the same depth, and there will be no over etching problems caused by a plurality of conductive plug openings 136 with different depths.

FIG. 3A to FIG. 3J are schematic cross-sectional views of a fabricating process of a memory device in a region 99 of FIG. 1R. FIG. 3A to FIG. 3J detail the steps of forming the barrier layer 126 and the conductive layer 124 and the plurality of protrusion portions 128 and 228.

Referring to FIG. 1R, FIG. 2B and FIG. 3A, before the middle layers 106 and 206 are each replaced by the barrier layer 126 and the conductive layer 124 respectively, and before forming the plurality of conductive plugs 138 and the partition wall SLT, the buried pads 118 and 218 (the buried pad 118e is shown in FIG. 3A) are buried in the insulating layers 108 and 208 (the insulating layer 108e is shown in the FIG. 3A) and the middle layers 106 and 206 (the middle layer 106e is shown in FIG. 3A). The material of the buried pads 118 and 218 may be the same as or different from the middle layers 106 and 206. In some embodiments, the material of the buried pads 118 and 218 and middle layers 106 and 206 includes silicon nitride. The buried pads 118 and 218 are staggered from each other. Therefore, there is no buried pad 218 disposed directly above each buried pad 118, and there is no buried pad 118 disposed directly below each buried pad 218.

Referring to FIG. 1R, FIG. 2C, and FIG. 3B, the plurality of conductive plug openings 136 (136a to 136f and 136A to 136F) are formed in the dielectric layer 222, the second staircase structure 204a, the protective layer 202, the dielectric layer 122, the first staircase structure 104a, and the protective layer 102. The conductive plug openings 136 may also be referred to as a plurality of contact openings 136. In embodiments of the disclosure, the plurality of conductive plug openings 136 may extend through the protective layer 102 to expose the interconnects of the interconnection structure below the protective layer 102. Therefore, the plurality of conductive plug openings 136 have substantially the same depth, and there will be no over etching problems caused by different depths.

In embodiments of the disclosure, each conductive plug opening 136 also passes through a buried pad 118 in the first staircase structure 104a or through a buried pad 218 in the second staircase structure 204a to divide the buried pad 118 or 218 into two portions P1 and P2. For example, the conductive plug opening 136 of FIG. 3B will later form the conductive plug 138 to pass through the dielectric layer 222, the second staircase structure 204a, the protective layer 202, the dielectric layer 122, the first staircase structure 104a, and the protective layer 102, and also pass through the buried pad 118e in the first staircase structure 104a. In some embodiments, the conductive plug opening 136 may pass through a centerline CL of the buried pad 118e such that the volumes of the two portions P1 and P2 are substantially equal. In other embodiments, the conductive plug opening 136 may be offset from the centerline CL of the buried pad 118e so that the volumes of the two portions P1 and P2 are different.

Referring to FIG. 3C, a sacrificial layer 140 is formed in the conductive plug opening 136. The sacrificial layer 140 may include a plurality of layers. In some embodiments, the sacrificial layer 140 includes a first sacrificial layer 140a, a second sacrificial layer 140b, and a third sacrificial layer 140c. The first sacrificial layer 140a is formed on the sidewalls and bottom of the conductive plug opening 136. The second sacrificial layer 140b is formed on the first sacrificial layer 140a. The third sacrificial layer 140c is formed on the second sacrificial layer 140b. The first sacrificial layer 140a and the second sacrificial layer 140b include insulating materials. For example, the first sacrificial layer 140a includes silicon oxide, and the second sacrificial layer 140b includes silicon nitride. The third sacrificial layer 140c includes polysilicon.

Referring to FIG. 1R, FIG. 2C, FIG. 3C, and FIG. 3D, the middle layers 106 and 206 and the buried pads 118 and 218 are each replaced with the barrier layer 126 and the conductive layer 124 respectively.

First, a trench 119 of the slit SLT may be formed in the dielectric layers 222 and 122, the stack structures 204 and 104, the second staircase structure 204a, and the first staircase structure 104a (shown in FIG. 1R and FIG. 2C). Although the cross-sectional view of FIG. 3D does not show the trench 119 of the slit SLT, it can be seen from FIG. 1R and FIG. 2C that the extending direction of the trench 119 of the slit SLT may be perpendicular to the direction of the I-I′ and II-II′ section lines. The trench 119 of the slit SLT may extend longitudinally to the bottom surfaces of the stack structures 204 and 104 and the staircase structures 204a and 104a, thereby exposing the sidewalls of the insulating layers 108 and 208 and the middle layers 106 and 206. Then, the middle layers 106 and 206 and the buried pads 118 and 218 may be removed to form a plurality of horizontal openings 121. The horizontal opening 121 exposes the upper and lower surfaces of the insulating layers 108 and 208 and the sidewalls of the sacrificial layer 140. At the same time, the sidewalls of the charge storage structure 128 are exposed in the memory cell array region A1. In some embodiments, the middle layers 106 and 206 and the buried pads 118 and 218 may be removed using a wet etching process. The wet etching process may use hot phosphoric acid as the etchant.

Next, referring to FIG. 3E, the barrier layer 126 (126c to 126e) and the conductive layer 124 (124c to 124e) are formed in the plurality of horizontal openings 121. First, a deposition process is performed to form a barrier material layer and a conductive material layer (not shown) in a plurality of voids and a plurality of slits SLT. The barrier material layer is, for example, silicon oxide or a high dielectric constant material with a dielectric constant greater than or equal to 7, such as aluminum oxide (Al₂O₃), hafnium oxide (HfO₂), lanthanum oxide (La₂O₅), transition metal oxides, and lanthanoid oxides, or a combination thereof. The conductive material layer (not shown) may be a single-layer structure or a multi-layer structure. In some embodiments, the conductive material layer (not shown) is, for example, tungsten, titanium, titanium nitride, or a combination thereof, but the disclosure is not limited thereto. Next, the barrier material layer and the conductive material layer located in the trench 119 of the slit SLT may be removed through an etching back process to form the barrier layer 126 and the conductive layer 124.

Next, referring to FIG. 1R and FIG. 3F, the sacrificial layer 140 in the conductive plug opening 136 is removed to expose the barrier layer 126, the insulating layers 108 and 208, and the interconnects of the interconnection structure below the conductive plug opening 136. The method of removing the sacrificial layer 140 is, for example, a wet etching method.

After that, referring to FIG. 1R and FIG. 3G, the barrier layer 126 exposed by the conductive plug opening 136 is removed to expose the sidewalls of the conductive layer 124. The method of removing the barrier layer 126 is, for example, a wet etching method.

Referring to FIG. 3H, part of the conductive layer 124 exposed by the conductive plug opening 136 is removed to form a plurality of groove rings 131 (131c to 131e). The method of removing part of the conductive layer 124 is, for example, a wet etching method. Among the groove rings 131c to 131e, the groove ring 131e is the position of the original buried pad 118, so its volume is larger than the groove rings 131c and 131d.

Referring to FIG. 3I, an insulating material 137′ is formed in the conductive plug opening 136 and the plurality of groove rings 131. The insulating material 137′ is along the sidewalls of the conductive plug opening 136, the surface of the barrier layer 126, the surface of the conductive layer 124, and the surfaces of the insulating layers 108 and 208 (shown in FIG. 1R). The insulating material 137′ includes an oxide, such as silicon oxide. The volume of the groove ring 131e is larger than the volume of the groove rings 131c and 131d. The groove rings 131c and 131d may be filled with the insulating material 137′, while the groove ring 131e is not filled with the insulating material 137′.

Referring to FIG. 3J, part of the insulation material 137′ is removed to completely remove the insulating material 137′ in part of the groove ring 131 (131e), and part of the insulating material 137′ in part of the groove ring 131 (131d and 131c) is left to form the insulating right 137 (137d and 137c). The method of removing part of the insulating material 137′ is, for example, a wet etching method. Since the groove ring 131e is not filled with the insulating material 137′ and has a large contact area with the etchant, during the etching process, the insulating material 137′ in the groove ring 131e may be completely removed, while part of the insulating material 137′ in the groove rings 131d and 131c is still left to form the insulating rings 137d and 137c.

Referring to FIG. 1R and FIG. 3K, the conductive plug 138 (138a to 138f) and the protrusion portions 128 (128a to 128f) and 228 (228a to 228f) are formed in the conductive plug openings 136. In some embodiments, the material of the conductive plug 138 and protrusion portions 128 and 228 may be the same. The conductive plug 138 may be a single-layer structure or a multi-layer structure. In some embodiments, the conductive plug 138 and the protrusion portions 128 and 228 may be formed simultaneously through the same process. In some embodiments, the conductive plug 138 and the protrusion portions 128 and 228 may be integrally formed. In some embodiments, the method of forming the conductive plug 138 and the protrusion portions 128 may include the following steps. First, a conductive plug material layer (not shown) filling the plurality of conductive plug openings 136 and groove ring 131e may be formed. The conductive plug material layer may be a single-layer structure or a multi-layer structure. In some embodiments, the material of the conductive plug material layer is, for example, tungsten, titanium, titanium nitride, or a combination thereof, but the disclosure is not limited thereto. In some embodiments, the method of forming the conductive plug material layer is, for example, a physical vapor deposition method or a chemical vapor deposition method. Next, the conductive plug material layer located outside the plurality of conductive plug openings 136 may be removed to form the conductive plug 138 and the protrusion portion 128. In some embodiments, the method of removing the conductive plug material layer located outside the plurality of conductive plug openings 136 is, for example, a chemical mechanical polishing (CMP) method. In some embodiments, the top surface of the conductive plug 138 and the top surface of the dielectric layer 222 are coplanar.

Referring to FIG. 1R, in some embodiments, the conductive plug 138 extends downwardly from the dielectric layer 222, passes through the plurality of conductive layers 124, the plurality of insulating layers 208 and 108, and the dielectric layer 102, and electrically connects with the interconnects of the interconnection structure below the dielectric layer 102. The conductive plug 138 is electrically connected to one of the plurality of conductive layers 124, and the conductive plug 138 is electrically insulated from other conductive layers 124 by the insulating ring 137.

Referring to FIG. 1R, the protrusion portion 128 surrounds the conductive plug 138. The protrusion portion 128 is embedded in the conductive layer 124 that is electrically connected to the conductive plug 138, and the top surface of the protrusion portion 128 is higher than the top surface of the conductive layer 124 that is electrically connected to the conductive plug 138. Referring to FIG. 3K, for example, the conductive plug 138e is shown passing through the dielectric layer 122, the plurality of insulating layers 108e, 108d, 108c, and 108b, the plurality of conductive layers 124e, 124d, and 124c, and the insulating rings 137d and 137c. The conductive plug 138e is electrically insulated from the conductive layers 124d and 124c by the insulating rings 137d and 137c. The protrusion portion 128e surrounds the conductive plug 138e. The protrusion portion 128e is embedded in the conductive layer 124e that is electrically connected to the conductive plug 138e, and the protrusion portion 128e is thicker, and a top surface SS1 thereof is higher than a top surface SS2 of the conductive layer 124 that is electrically connected to the conductive plug 138.

Referring to FIG. 1R, since the protrusion portions 128 and 228 of the embodiment of the disclosure have a larger thickness than the conductive layer 124, compared with the situation where the conductive plug 138 directly contacts the sidewall of the conductive layer 124, the arrangement of the protrusion portions 128 and 228 of the embodiment of the disclosure may increase the contact area with the conductive plug 138.

FIG. 4A to FIG. 4C are top views of some stages of a fabricating process of a memory device according to other embodiments of the disclosure.

FIG. 4A shows the plurality of protrusion portions 128 projected onto the surface of the substrate 100. The plurality of protrusion portions 128 are disposed on each of the steps S1, S2, and S3 of the first staircase structure 104a. The plurality of protrusion portions 128 disposed at different steps S1, S2, and S3 may be arranged in a plurality of rows and spaced apart by one row. In the embodiment, the plurality of protrusion portions 128 are arranged in rows R1 and R3. Rows R2 and R4 are not disposed with the protrusion portions 128. There is a distance D1 between the protrusion portions 128 at the same step S1, S2, or S3. The distance D1 is greater than a distance D3 between the conductive plugs 138 at the same step S1, S2, or S3 (shown in FIG. 4C). In other words, the protrusion portion 128 is disposed quite loosely, which may avoid the problem of abnormal coupling between adjacent protrusion portions 128.

FIG. 4B shows the plurality of protrusion portions 228 projected onto the surface of the substrate 100. The plurality of protrusion portions 228 are disposed on each of the steps S1′, S2′, and S3′ of the second staircase structure 204a. The plurality of protrusion portions 228 disposed at different steps S1′, S2′ and S3′ may be arranged in a plurality of rows and spaced one row apart. In the embodiment, the plurality of protrusion portions 228 are arranged in rows R2 and R4. Rows R1 and R3 are not disposed with the protrusion portions 228. There is a distance D2 between the protrusion portions 228 at the same step S1′, S2′, or S3′. The distance D2 is greater than the distance D3 between the conductive plugs 138 at the same step S1′, S2′, or S3′ (shown in FIG. 4C). In other words, the protrusion portion 228 is disposed quite loosely, which may avoid the problem of abnormal coupling between adjacent protrusion portions 228.

FIG. 4C shows the protrusion portions 128 and 228 projected onto the surface of the substrate 100. The protrusion portions 128 and 228 projected onto the surface of the substrate are staggered from each other. In the embodiment, the protrusion portions 128 are disposed in the odd-numbered columns R1 and R3, the protrusion portions 228 are disposed in the even-numbered columns R2 and R4, and the protrusion portions 128 and 228 are arranged in an array.

FIG. 4C also shows a plurality of conductive plugs 138 projected onto the surface of substrate 100. The plurality of conductive plugs 138 are arranged in an array. The conductive plugs 138 of row R1 pass through the protrusion portions 128 of row R1, the conductive plugs 138 of row R2 pass through the protrusion portions 228 of row R2, the conductive plugs 138 of row R3 pass through the protrusion portions 128 of row R3, and the conductive plugs 138 of row R4 pass through the protrusion portions 228 of row R4. The number of conductive plugs 138 is greater than the number of protrusion portions 128 and is greater than the number of protrusion portions 228. Each conductive plug 138 is surrounded by and electrically coupled to one of the protrusion portions 128 and 228, and is coupled to the conductive layer 124 (shown in FIG. 1R and FIG. 2C). In other words, the protrusion portions 128 and 228 are between the conductive plug 138 and the conductive layer 124 and are electrically connected to the conductive plug 138 and the conductive layer 124.

In the above embodiment, the protrusion portions 128 at different steps S1, S2, and S3 are arranged in odd-numbered rows R1 and R3, and the protrusion portions 228 at different steps S1′, S2′, and S3′ are arranged in even-numbered rows R2 and R4. In other words, the rows R1 and R3 of protrusion portions 128 and the rows R2 and R4 of protrusion portions 228 alternate with each other. However, embodiments of the disclosure are not limited thereto. The protrusion portions 128 and 228 may be disposed in other arrangements.

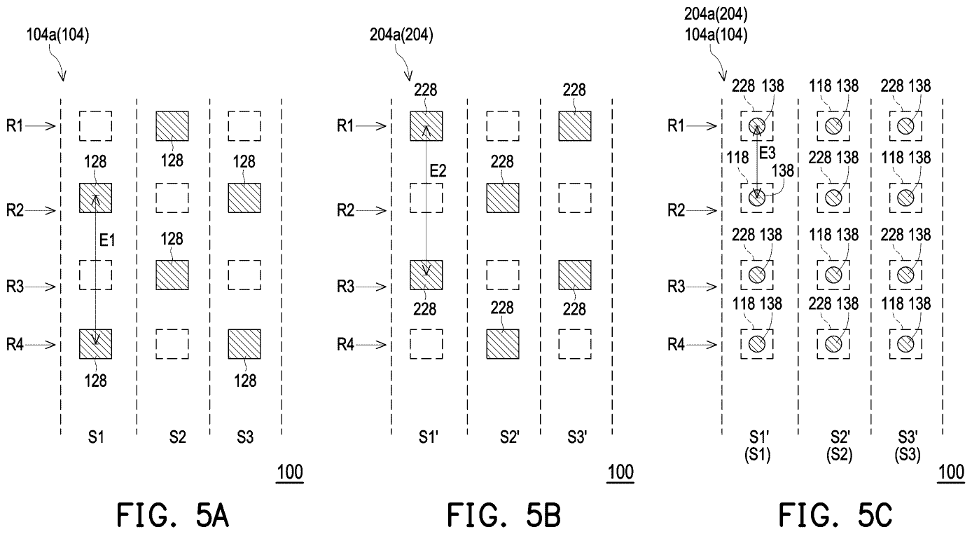

FIG. 5A to FIG. 5C are top views of some stages of a fabricating process of a memory device according to other embodiments of the disclosure.

FIG. 5A shows the plurality of protrusion portions 128 projected onto the surface of the substrate 100. The plurality of protrusion portions 128 are disposed on each of the steps S1, S2, and S3 of the first staircase structure 104a. The plurality of protrusion portions 128 at the same step S1, S2, or S3 are spaced apart from each other. The plurality of protrusion portions 128 at adjacent steps are arranged staggered or spaced apart from each other. There is a distance E1 between the protrusion portions 128 at the same step S1, S2, or S3. The distance D1 is greater than a distance E3 between the conductive plugs 138 at the same step S1, S2, or S3 (shown in FIG. 5C). In other words, the protrusion portion 128 is disposed quite loosely, which may avoid the problem of abnormal coupling between adjacent protrusion portions 128.

FIG. 5B shows the plurality of protrusion portions 228 projected onto the surface of the substrate 100. The plurality of protrusion portions 228 are disposed on each of the steps S1′, S2′, and S3′ of the second staircase structure 204a. The plurality of protrusion portions 228 at the same step S1′, S2′, or S3′ are spaced apart from each other. The plurality of protrusion portions 228 at adjacent steps are arranged staggered or spaced apart from each other. There is a distance E2 between the protrusion portions 228 at the same step S1′, S2′, or S3′. The distance E2 is greater than the distance E3 between the conductive plugs 138 at the same steps S1′, S2′, or S3′ (shown in FIG. 5C). In other words, the protrusion portion 228 is disposed quite loosely, which may avoid the problem of abnormal coupling between adjacent protrusion portions 228.

FIG. 5C shows the protrusion portions 128 and 228 projected onto the surface of the substrate 100. The projections 128 and 228 projected onto the surface of the substrate are staggered from each other. There are protrusion portions 128 and 228 in each row R1, R2, R3, and R4. In rows R1 and R3, the protrusion portion 128 is between two protrusion portions 228. In rows R2 and R4, the protrusion portion 228 is between the two protrusion portions 128. Furthermore, in the embodiment, each protrusion portion 128 is surrounded by the protrusion portion 228, and each protrusion portion 228 is surrounded by the protrusion portion 128. In some embodiments, at least one protrusion portion 128 is disposed among four protrusion portions 228, and the four protrusion portions 228 are respectively disposed on the upper, lower, left, and right sides of the protrusion portion 128. At least one protrusion portion 228 is disposed among the four protrusion portions 128, and the four protrusion portions 128 are respectively disposed on the upper, lower, left, and right sides of the protrusion portion 228. In the embodiment, the protrusion portions 128 and 228 are arranged in an array.

FIG. 5C also shows the plurality of conductive plugs 138 projected onto the surface of substrate 100. The plurality of conductive plugs 138 are arranged in an array. The conductive plugs 138 of each row R1, R2, R3, and R4 pass through the protrusion portions 128 and 228 of the corresponding row R1, R2, R3, and R4. The number of conductive plugs 138 is greater than the number of protrusion portions 128 and is greater than the number of protrusion portions 228. Each conductive plug 138 is surrounded by and electrically coupled to one of the protrusion portions 128 and 228, and is coupled to the conductive layer 124 (shown in FIG. 1R and FIG. 2C). In other words, the protrusion portions 128 and 228 are between the conductive plug 138 and the conductive layer 124 and are electrically connected to the conductive plug 138 and the conductive layer 124.

In the above embodiments, the memory device having a first stack structure, a second stack structure, a first staircase structure 104a, and a second staircase structure 204a is used for explanation. However, embodiments of the disclosure are not limited thereto. In some embodiments, the memory device further includes more stack structures and more staircase structures.

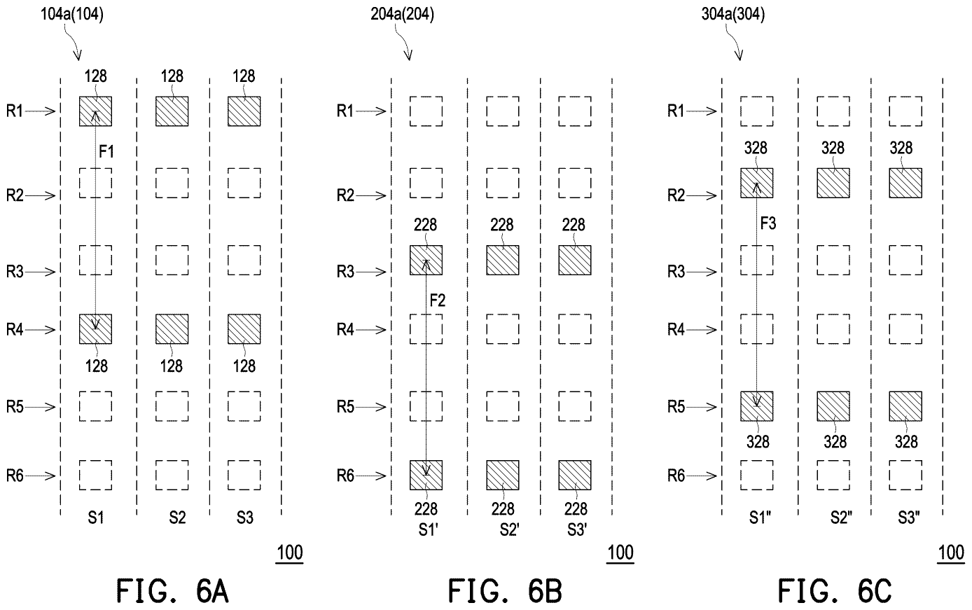

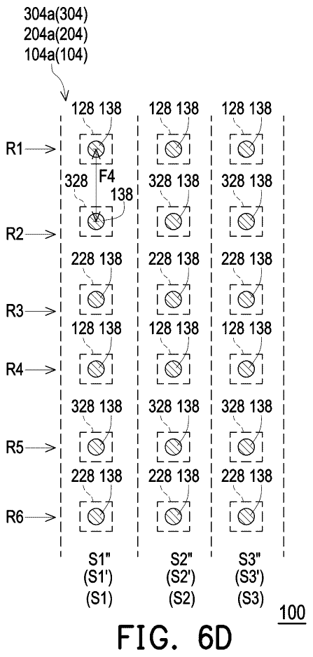

FIG. 6A to FIG. 6D are top views of some stages of a fabricating process of a memory device according to other embodiments of the disclosure.

Referring to FIG. 6A to FIG. 6D, the memory device further includes a third stack structure 304. The third stack structure 304 includes a third staircase structure 304a. The third staircase structure 304a is disposed above the second staircase structure 204a. The third stack structure 304 may have a similar structure to the first stack structure 104 or the second stack structure 204 (shown in FIG. 1R and FIG. 2C). The third staircase structure 304a may have a similar structure to the first staircase structure 104a or the second staircase structure 204a (shown in FIG. 1R and FIG. 2C).

FIG. 6A shows the plurality of protrusion portions 128 projected onto the surface of the substrate 100. The plurality of protrusion portions 128 are disposed on each of the steps S1, S2, and S3 of the first staircase structure 104a. The plurality of protrusion portions 128 disposed at different steps S1, S2 and S3 may be arranged in a plurality of rows and spaced apart by two rows. In the embodiment, the plurality of protrusion portions 128 are arranged in rows R1 and R4. Rows R2, R3, R5, and R6 are not provided with protrusion portions 128. There is a distance F1 between the protrusion portions 128 at the same step S1, S2, or S3. The distance F1 is greater than a distance F4 between the conductive plugs 138 at the same step S1, S2, or S3 (shown in FIG. 6D). In other words, the protrusion portion 128 is disposed quite loosely, which may avoid the problem of abnormal coupling between adjacent protrusion portions 128.

FIG. 6B shows the plurality of protrusion portions 228 projected onto the surface of the substrate 100. The plurality of protrusion portions 228 are disposed on each of the steps S1′, S2′, and S3′ of the second staircase structure 204a. The plurality of protrusion portions 228 disposed at different steps S1′, S2′, and S3′ may be arranged in a plurality of rows and spaced apart by two rows. In the embodiment, the plurality of protrusion portions 228 are arranged in rows R3 and R6. Rows R1, R2, R4, and R5 are not disposed with the protrusion portions 228. There is a distance F2 between the protrusion portions 228 at the same level S1′, S2′, or S3′. The distance F2 is greater than the distance F4 between the conductive plugs 138 at the same step S1′, S2′, or S3′ (shown in FIG. 6D). In other words, the protrusion portion 228 is disposed quite loosely, which may avoid the problem of abnormal coupling between adjacent protrusion portions 228.

FIG. 6C shows a plurality of protrusion portions 328 projected onto the surface of the substrate 100. The plurality of protrusion portions 328 are disposed on each of the steps S1″, S2″, and S3″ of the third staircase structure 304a. The plurality of protrusion portions 328 disposed at different steps S1″, S2″, and S3″ may be arranged in a plurality of rows and spaced by two rows. In the embodiment, the plurality of protrusion portions 328 are arranged in rows R2 and R5. Rows R1, R3, R4, and R6 are not disposed with the protrusion portions 328. There is a distance F3 between the protrusion portions 328 at the same step S1″, S2″, or S3″. The distance F3 is greater than the distance F4 between the conductive plugs 138 at the same step S1″, S2″, or S3″ (shown in FIG. 6D). In other words, the protrusion portion 328 is disposed quite loosely, which may avoid the problem of abnormal coupling between adjacent protrusion portions 328.

FIG. 6D shows the protrusion portions 128, 228, and 328 projected onto the surface of the substrate 100. The projections 128, 228, and 328 projected onto the surface of the substrate are staggered from each other. In the embodiment, the protrusion portions 128 are disposed in rows R1 and R4, the protrusion portions 328 are disposed in rows R3 and R6, the protrusion portions 228 are disposed in rows R2 and R5, and the protrusion portions 128, 228, and 328 are arranged in an array.

FIG. 6D also shows the plurality of conductive plugs 138 projected onto the surface of substrate 100. The plurality of conductive plugs 138 extend through the third staircase structure 304a, the second staircase structure 204a, and the first staircase structure 104a. The plurality of conductive plugs 138 are arranged in an array. The conductive plugs 138 of rows R1 and R4 each pass through the protrusion portions 128 of rows R1 and R4 respectively, the conductive plugs 138 of rows R2 and R5 each pass through the protrusion portions 328 of rows R2 and R5, and the conductive plugs 138 of rows R3 and R6 each pass through the protrusion portions 228 of rows R3 and R6. The number of conductive plugs 138 is greater than the number of protrusion portions 128, the number of protrusion portions 228, and the number of protrusion portions 328. Each conductive plug 138 is surrounded by and electrically coupled to one of the protrusion portions 128, 228, and 328, and then coupled to the conductive layer 124 (shown in FIG. 1R and FIG. 2C). In other words, the protrusion portions 128, 228, and 328 are between the conductive plug 138 and the conductive layer 124 and are electrically connected to the conductive plug 138 and the conductive layer 124.

In the above embodiments, the memory device having the first stack structure 104, the second stack structure 204, the third stack structure 304, the first staircase structure 104a, the second staircase structure 204a, and the third staircase structure 304a is used for explanation. However, embodiments of the disclosure are not limited thereto. In some embodiments, the memory device may also include more stack structures and more staircase structures.

Embodiments of the disclosure may be applied to a NAND flash memory, a NOR flash memory, or other flash memories.

Based on the above, in the memory device and the method of fabricating the same proposed in the embodiment of the disclosure, the plurality of conductive plugs connected to the plurality of conductive layers have substantially the same depth. Therefore, there will be no over etching problems caused by the plurality of conductive plug openings with different depths, so that the process margin of the conductive plug openings may be improved and the process yield may be increased. Furthermore, the contact area between the conductive layer and the conductive plug may be increased and the contact resistance may be reduced by forming the protrusion portion around the conductive plug.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A memory device, comprising:
a substrate;
a first stack structure located on the substrate, wherein the first stack structure comprises a plurality of first conductive layers and a plurality of first insulating layers alternating with each other, and the first stack structure in a staircase region of the substrate comprises a first staircase structure;
a second stack structure located on the first stack structure, wherein the second stack structure comprises a plurality of second conductive layers and a plurality of second insulating layers alternating with each other, and the second stack structure in the staircase region of the substrate comprises a second staircase structure;
a plurality of first protrusion portions disposed on the plurality of first conductive layers of the first staircase structure and electrically connected to the plurality of first conductive layers;
a plurality of second protrusion portions disposed on the plurality of second conductive layers of the second staircase structure and electrically connected to the plurality of second conductive layers;
a plurality of conductive plugs extending through the second staircase structure and the first staircase structure, wherein each conductive plug is electrically connected to one of the plurality of first conductive layers and the plurality of second conductive layers respectively, and is surrounded by and electrically connected to one of the plurality of first protrusion portions and the plurality of second protrusion portions.

2. The memory device according to claim 1, wherein the plurality of first protrusion portions and the plurality of second protrusion portions projected onto a surface of the substrate are staggered from each other.

3. The memory device according to claim 2, wherein the plurality of first protrusion portions and the plurality of second protrusion portions are projected onto the surface of the substrate to form an array.

4. The memory device according to claim 3, wherein viewed from the surface projected onto the substrate, the plurality of first protrusion portions at different steps in the first staircase structure are arranged into a plurality of first rows, the plurality of second protrusion portions at different steps in the second staircase structure are arranged into a plurality of second rows, and the plurality of first rows and the plurality of second rows alternate with each other.

5. The memory device according to claim 3, wherein viewed from the surface projected onto the substrate, the plurality of first protrusion portions at adjacent steps in the first staircase structure are arranged staggered from each other, and the plurality of second protrusion portions at adjacent steps in the second staircase structure are arranged staggered from each other.

6. The memory device according to claim 3, further comprising:
a plurality of channel pillars extending through the second stack structure and the first stack structure in a memory cell array region of the substrate; and
a plurality of charge storage structures, surrounding the plurality of channel pillars.

7. The memory device according to claim 2, further comprising:
a third stack structure located on the second stack structure, wherein the third stack structure comprises a plurality of third conductive layers and a plurality of third insulating layers alternating with each other, and the third stack structure in the staircase region of the substrate comprises a third staircase structure; and
a plurality of third protrusion portions disposed on the plurality of third conductive layers of the third staircase structure and electrically connected to the plurality of third conductive layers,
wherein the plurality of conductive plugs further extend through the third staircase structure, and each conductive plug is electrically connected to one of the plurality of first conductive layers, the plurality of second conductive layers, and the plurality of third conductive layers, and is surrounded by and electrically connected to one of the plurality of first protrusion portions, the plurality of second protrusion portions, and the plurality of third protrusion portions.

8. The memory device according to claim 7, wherein viewed from the surface projected onto the substrate, the plurality of first protrusion portions at different steps in the first staircase structure are arranged into a plurality of first rows, the plurality of third protrusion portions at different steps in the third staircase structure are arranged into a plurality of second rows, and the plurality of second protrusion portions at different steps in the second staircase structure are arranged into a plurality of third rows.

9. The memory device according to claim 8, wherein the plurality of first protrusion portions, the plurality of second protrusion portions, and the plurality of third protrusion portions are projected onto the surface of the substrate to form an array.

10. The memory device according to claim 9, wherein,
a distance between the plurality of first protrusion portions at a same step is greater than a distance between the plurality of conductive plugs;
a distance between the plurality of second protrusion portions at a same step is greater than the distance between the plurality of conductive plugs; and
a distance between the plurality of third protrusion portions at a same step is greater than the distance between the plurality of conductive plugs.

11. A method of forming a memory device, comprising:
providing a substrate;
forming a first stack structure on the substrate, wherein the first stack structure comprises a plurality of first conductive layers and a plurality of first insulating layers alternating with each other, and the first stack structure in a staircase region of the substrate comprises a first staircase structure;
forming a second stack structure located on the first stack structure, wherein the second stack structure comprises a plurality of second conductive layers and a plurality of second insulating layers alternating with each other, and the second stack structure in the staircase region of the substrate comprises a second staircase structure;
forming a plurality of first protrusion portions on the plurality of first conductive layers of the first staircase structure to be electrically connected to the plurality of first conductive layers;
forming a plurality of second protrusion portions on the plurality of second conductive layers of the second staircase structure to be electrically connected to the plurality of second conductive layers; and
forming a plurality of conductive plugs extending through the second staircase structure and the first staircase structure, wherein each conductive plug is electrically connected to one of the plurality of first conductive layers and the plurality of second conductive layers respectively, and is surrounded by and electrically connected to one of the plurality of first protrusion portions and the plurality of second protrusion portions.

12. The method of forming the memory device according to claim 11, wherein,
forming the first stack structure and forming the plurality of first protrusion portions comprises:
forming a plurality of first middle layers and the first insulating layer alternating with each other;
patterning the plurality of first middle layers and the first insulating layer into a plurality of first steps, and forming a plurality of first buried pads in the plurality of first steps; and
replacing the plurality of first middle layers and the plurality of first buried pads with a first conductive material to form the plurality of first conductive layers and the plurality of first protrusion portions; and
forming the second stack structure and forming the plurality of second protrusion portions comprises:
forming a plurality of second middle layers and the second insulating layer alternating with each other;
patterning the plurality of second middle layers and the second insulating layer into a plurality of second steps, and forming a plurality of second buried pads in the plurality of second steps; and
replacing the plurality of second middle layers and the plurality of second buried pads with a second conductive material to form the plurality of second conductive layers and the plurality of second protrusion portions.

13. The method of forming the memory device according to claim 12, wherein the plurality of first protrusion portions and the plurality of second protrusion portions projected onto a surface of the substrate are staggered from each other, and the plurality of first protrusion portions and the plurality of second protrusion portions are projected onto the surface of the substrate to form an array.

14. The method of forming the memory device according to claim 13, wherein viewed from the surface projected onto the substrate, the plurality of first protrusion portions at different steps in the first stack structure are arranged into a plurality of first rows, the plurality of second protrusion portions at different steps in the second stack structure are arranged into a plurality of second rows, and the plurality of first rows and the plurality of second rows alternate with each other.

15. The method of forming the memory device according to claim 13, wherein viewed from the surface projected onto the substrate, the plurality of first protrusion portions at adjacent steps in the first stack structure are arranged staggered from each other, and the plurality of second protrusion portions at adjacent steps in the second stack structure are arranged staggered from each other.

16. The method of forming the memory device according to claim 13, further comprising:
forming a plurality of channel pillars to extend through the second stack structure and the first stack structure; and
forming a plurality of charge storage structures to surround the plurality of channel pillars.

17. The method of forming the memory device according to claim 12, further comprising:
forming a third stack structure on the second stack structure, wherein the third stack structure comprises a plurality of third conductive layers and a plurality of third insulating layers alternating with each other, and the third stack structure in the staircase region of the substrate comprises a third staircase structure; and
forming a plurality of third protrusion portions on the plurality of third conductive layers of the third stack structure to be electrically connected to the plurality of third conductive layers,
wherein the plurality of conductive plugs also extend through the third staircase structure, and each conductive plug is electrically connected to one of the plurality of first conductive layers, the plurality of second conductive layers, and the plurality of third conductive layers, and is surrounded by and electrically connected to one of the plurality of first protrusion portions, the plurality of second protrusion portions, and the plurality of third protrusion portions.

18. The method of forming the memory device according to claim 17, wherein viewed from a surface projected onto the substrate, the plurality of first protrusion portions at different steps in the first stack structure are arranged into a plurality of first rows, the plurality of third protrusion portions at different steps in the third stack structure are arranged into a plurality of second rows, and the plurality of second protrusion portions at different steps in the second stack structure are arranged into a plurality of third rows.

19. The method of forming the memory device according to claim 18, wherein the plurality of first protrusion portions, the plurality of second protrusion portions, and the plurality of third protrusion portions are projected onto the surface of the substrate to form an array.

20. The method of forming the memory device according to claim 19, wherein,
a distance between the plurality of first protrusion portions at a same step is greater than a distance between the plurality of conductive plugs;
a distance between the plurality of second protrusion portions at a same step is greater than the distance between the plurality of conductive plugs; and
a distance between the plurality of third protrusion portions at a same step is greater than the distance between the plurality of conductive plugs.
